(19) United States
(12) Patent Application Publication
(10) Pub. No.: US 2005/0012211 A1
(43) Pub. Date: Jan. 20, 2005

(54) Under-bump metallugical structure

(76) Inventors: Moriss Kung, Hsien-Tien City (TW); Kwun-Yao Ho, Hsien-Tien City (TW)

Correspondence Address: J C PATENTS, INC., 4 VENTURE, SUITE 250, IRVINE, CA, 92618, US

(21) Appl. No.: 10/921,369

(22) Filed: Aug. 18, 2004

Related U.S. Application Data
(63) Continuation-in-part of application No. 10/065,103, filed on Sep. 17, 2002.

(30) Foreign Application Priority Data
May 29, 2002 (TW) 91111431

(51) Int. Cl. H01L 29/06

(52) U.S. Cl. 257/734; 257/10

(57) ABSTRACT

An under-bump metallurgical structure between the bonding pad of a die or a substrate and a solder bump such that the principle constituent of the solder bump is lead-tin alloy or lead-free alloy. The under-bump metallurgical structure at least includes a metallic layer and a buffer metallic structure. The metallic layer is formed over the bonding pads of the die. Major constituents of the metallic layer include copper, aluminum, nickel, silver or gold. The buffer metallic structure between the metallic layer and the solder bump is capable of reducing the growth of inter-metallic compound due to chemical reaction between the metallic constituents of the metallic layer and tin from the solder bump.

### CROSS-REFERENCE TO RELATED APPLICATION

This application is a continuation-in-part of a prior application Ser. No. 10/065,103, filed Sep. 17, 2002. The prior application Ser. No. 10/605,305 claims the priority benefit of Taiwan application serial no. 91111431, filed May 29, 2002.

### BACKGROUND OF THE INVENTION

1. Field of Invention

The present invention relates to an under-bump metallurgical structure between the solder pad and the solder bump of a chip or a substrate. More particularly, the present invention relates to an under-bump metallurgical structure between the solder pad and the solder bump of a chip.

2. Description of Related Art

Flip chip interconnect technology utilizes an area array arrangement to place a plurality of pads on the active surface of a die. Each pad has a bump such as a solder bump and the pads may contact corresponding contact points on a substrate or a printed circuit board (PCB) as the die is flipped over. Because flip chip technology has the capacity to produce high pin count chip packages with a small packaging dimension and short signal transmission path, it has been widely adopted by chip manufacturers. Many types of bumps are currently available including solder bumps, gold bumps, conductive plastic bumps and polymer bumps. However, the most common one is solder bumps.

FIG. 1 is a cross-sectional view of a conventional under-bump metallic layer between the bonding pad of a die and a bump. As shown in FIG. 1, the die 10 has an active surface 12 with a passivation layer 14 and a plurality of bonding pads 16 (only one is shown) thereon and the passivation layer 14 exposes the bonding pads 16. In fact, the active surface 12 of the die 10 refers to the side where all the active devices are fabricated. Furthermore, there is an under-bump metallic layer 100 over the bonding pads 16 serving as a junction interface between the bonding pad 16 and a bump 18.

The under-bump metallic layer 100 has a multiple metallic layer structure that mainly includes an adhesion layer 102, a barrier layer 104 and a wettable layer 106. The adhesion layer 102 strengthens the bond between the underlying bonding pad 16 and the overhead barrier layer 14. In general, the adhesion layer 102 is made from chromium, titanium, titanium-tungsten alloy, chromium-copper alloy, aluminum or nickel. The barrier layer 104 prevents cross-diffusion between upper and lower metallic layers. In general, the barrier layer 104 is made from chromium-copper alloy, nickel or nickel-vanadium alloy. The wettable layer 106 is capable of increasing the wetting capacity with the overhead solder bump 18. In general, the wettable layer 106 is made from copper, nickel or gold. Note that if the wettable layer 106 is made from copper, the under-bump metallic layer 100 may further include an oxidation resistant layer (not shown) over the wettable layer 106 for preventing surface oxidation. In general, the oxidation resistant layer is made from gold or other organic surface protective material.

Since lead-tin alloy has good solderability, most solder bumps 18 are made from lead-tin alloy. Note that after the solder bump 18 is properly positioned over the under-bump metallic layer 100 through a plating, a printing or some other method, a reflow operation must be carried out. The reflow operation not only attaches the underside of the solder bump 18 firmly to the wettable layer 106, but also transforms the solder bump 18 into a lump of material having a roughly spherical profile. Thereafter, the die 10 is flipped over so that the solder bumps 18 on the active surface 12 are able to contact corresponding contact points on a substrate (or a printed circuit board). Another reflow operation is conducted so that the upper surface of the solder bumps 18 are bonded to the contacts on the substrate (or printed circuit board) (not shown).

If the top layer of the under-bump metallic layer 100 is made from copper, nickel, aluminum, silver or gold, after several heat treatment such as reflow, the tin within the solder bump 18 may react chemically with copper, nickel or gold within the under-bump metallic layer 100. Hence, an inter-metallic compound (IMC) may be formed between the solder bump 18 and the under-bump metallic layer 100. Lead-copper is the most easily formed inter-metallic compound, tin-nickel is the second most easily formed inter-metallic compound while tin-gold is the third most easily formed inter-metallic compound. Note that the inter-metallic compound is not so conductive layer that may increase the electrical resistance between the solder bump 18 and the under-bump metallic layer 100. Accordingly, electrical performance of the flip chip package after the die is enclosed within may deteriorate. Moreover, adhesive strength at the junction between the solder bump 18 and the under-bump metallic layer 100 may be weakened.

### SUMMARY OF THE INVENTION

Accordingly, one object of the present invention is to provide an under-bump metallurgical structure between the bonding pad and the solder bump of a die such that thickness of the layer of inter-metallic compound between the under-bump metallurgical structure and the solder bump is reduced. Hence, mechanical strength and electrical performance of the package that the die is enclosed within is improved.

To achieve these and other advantages and in accordance with the purpose of the invention, as embodied and broadly described herein, the invention provides an under-bump metallurgical structure between a bonding pad of a die and a solder bump. The solder bump is mainly made from lead-tin alloy. The under-bump metallurgical structure has a metallic layer over the bonding pads and a buffer metallic layer between the metallic layer and the solder pad for reducing the growth of inter-metallic compound between the metallic layer and the solder bump.

To achieve these and other advantages and in accordance with the purpose of the invention, as embodied and broadly described herein, the invention further provides an under-bump metallurgical structure between a bonding pad of a die and a solder bump. The under-bump metallurgical structure has a metallic layer over the bonding pads and a buffer metallic layer between the metallic layer and the solder pad for reducing the growth of inter-metallic compound between the metallic layer and the solder bump, and the buffer metallic structure is principally constituent of an element of the composition of the solder bump.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a cross-sectional view of a conventional under-bump metallic layer between the bonding pad of a die and a bump.

FIGS. 2A to 2F are schematic cross-sectional views showing different types of under-bump metallurgical structures between the bonding pad of a die and a solder bump according to a first preferred embodiment of this invention.

FIGS. 3A to 3G are schematic cross-sectional views showing the progression of steps for fabricating the first type of under-bump metallurgical structure as shown in FIG. 2A.

FIGS. 4A to 4H are schematic cross-sectional views showing different types of under-bump metallurgical structures between the bonding pad of a die and a solder bump according to a second preferred embodiment of this invention;

FIGS. 5A to 5H are schematic cross-sectional views showing the progression of steps for fabricating the first type of under-bump metallurgical structure as shown in FIG. 4A.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

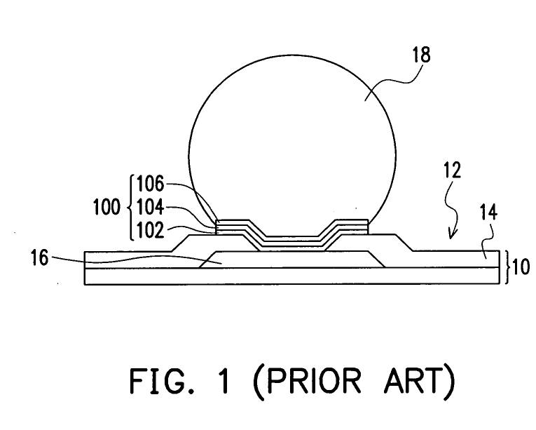

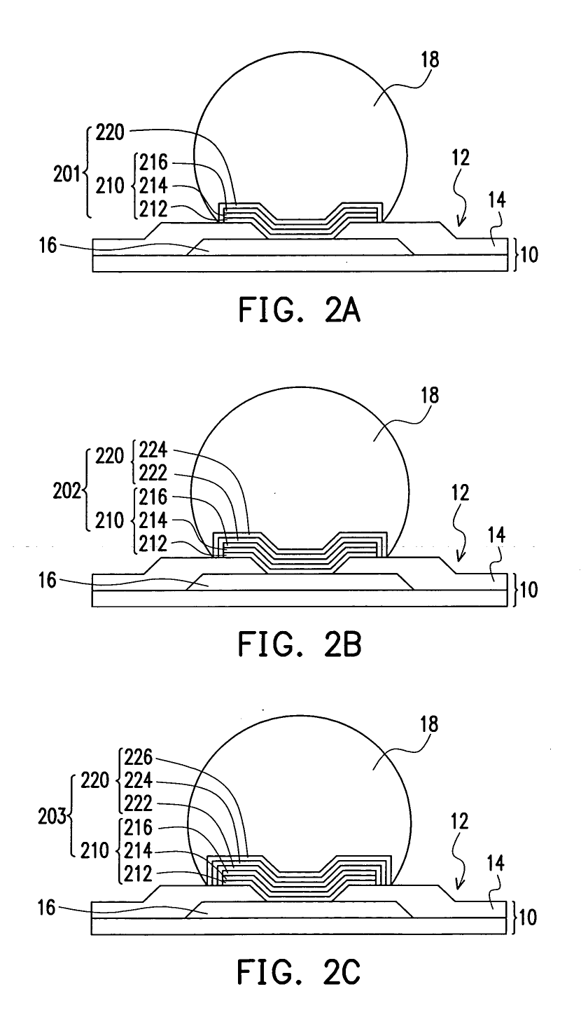

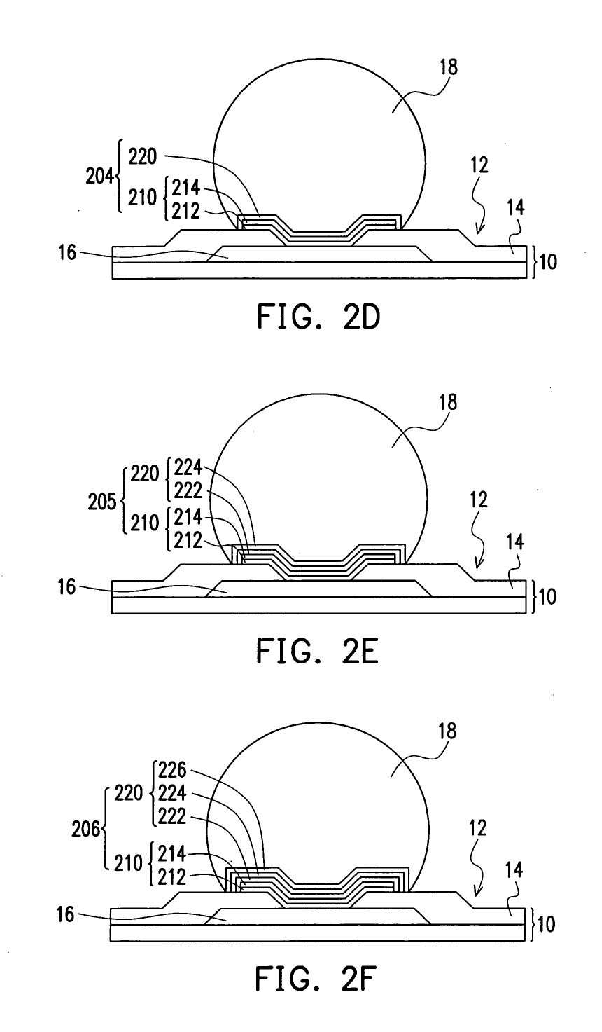

FIG. 2A is a schematic cross-sectional view showing a first type of under-bump metallurgical structure between the bonding pad of a die and a solder bump according to a preferred embodiment of this invention. As shown in FIG. 2A, the die 10 has an active surface 12 with a passivation layer 14 and a plurality of bonding pads 16 (only one is shown) thereon. The passivation layer and the bonding pads 16 are formed over the active surface 12 of the die 10 such that the passivation layer 14 exposes the bonding pads 16. Note that the active surface 12 of the die 10 refers to the side where all active devices are formed. To provide an interface for joining the bonding pad 16 and the solder bump 18 together, this invention proposes a first type of under-bump metallurgical structure 201 between the bonding pad 16 and the solder bump 18. The first type of under-bump metallurgical structure 201 includes a metallic layer 210 and a buffer metallic layer (or an inter-metallic compound growth buffer layer) 220. The metallic layer 210 is formed over the bonding pad 16 and the buffer metallic layer 220 is formed between the metallic layer 210 and the solder bump 18. In addition, the metallic layer 210 further includes an adhesion layer 212, a barrier layer 214 and a wettable layer 216. The adhesion layer 212 is formed over the bonding pad 16, the barrier layer 214 is formed over the adhesion layer 212 and the wettable layer 216 is formed between the barrier layer 214 and the buffer metallic layer 220. Since the metallic layer 210 has a material and structural composition identical to the under-bump metallic layer 100 as shown in FIG. 1, detailed description is not repeated here.

In general, the wettable layer 216 is made from a material including copper or gold. If the wettable layer 216 is made from copper, an anti-oxidation layer (not shown) may be coated over the wettable layer 216 to prevent surface oxidation of the copper wettable layer 216. The anti-oxidation layer is commonly a thin layer of gold. However, if major constituents of the wettable layer 216 are copper, nickel or gold, the tin within the solder bump 18 may easily react chemically with copper, nickel or gold within the under-bump metallic layer 210 after a thermal treatment of the solder bump 18. Ultimately, a layer of inter-metallic compound is formed between the solder bump 18 and the under-bump metallic layer 210. In this invention, the buffer metallic layer 220 of the first type of under-bump metallurgical structure 210 is formed between the wettable layer 216 and the solder bump 18 so that growth of the inter-metallic compound is reduced.

To prevent the buffer metallic layer 220 from melting during thermal treatment (for example, a reflow operation) and losing its functional capacity, the buffer metallic layer 220 must have a melting point higher than the solder bump 18 so that buffer metallic layer 220 does not melt and is not completely dissolved into the solder bump 18 while the solder bump 18 is melting. Furthermore, to provide a good bonding strength between the buffer metallic layer 220 and the solder bump 18, the buffer metallic layer 220 must easily wet the solder bump 18. Thus, the buffer metallic layer 220 is preferably made from lead, a high melting point lead-tin alloy or some other materials.

In addition, the buffer metallic layer 220 may be principally constituent of one element of the composition of the solder bump 18. For an example, when the solder bump 18 is constituent of lead-tin alloy, the buffer metallic layer 220 may be principally constituent of lead or tin. For another example, when the solder bump 18 is constituent of lead-tin-copper alloy, the buffer metallic layer 220 may be principally constituent of lead, tin, or copper. In order to prevent the under-bump metallic layer 210 from being attacked by the solder bump 18, the thickness of the buffer metallic layer 220 is usually greater than that of under-bump metallic layer 210. For example, when the thickness of the under-bump metallic layer 210 is about 100 to 200 nm, the thickness of the buffer metallic layer 220 is greater than 1 micron, or about 0.5 micron to 5 microns. When the buffer metallic layer 220 may be principally constituent of one element of the composition of the solder bump 18, the alloy formed from the buffer metallic layer 220 with the solder bump 18 is similar to the composition of solder bump 18 with a continuous constitution gradient, so that no structure weak point forming when the top portion of the under-bump metallic layer 210 is not made of any one of the composition of the solder bumps 18.

FIGS. 2B and 2C are schematic cross-sectional views of the second and the third type of under-bump metallurgical structures between the bonding pad 16 of the die 10 and the solder bump 18. As shown in FIG. 2B, the second type of under-bump metallurgical structure 202 is very similar to the first type of under-bump metallurgical structure 201. The second type of under-bump metallurgical structure 202 similarly has the metallic layer 210 in the first type of under-bump metallurgical structure 201. However, the buffer metallic layer 220 further includes a first buffer metallic layer 222 and a second buffer metallic layer 224. The first buffer metallic layer 222, for example, is a lead layer formed over the wettable layer 216. The second buffer metallic layer 224, for example, is a tin layer formed between the first buffer metallic layer 222 and the solder bump 18. As shown in FIG. 2C, the third under-bump metallurgical structure 203 is also similar to the first type of under-bump metallurgical structure 201. The third under-bump metallurgical layer 203 similarly has the metallic layer 210 of the first under-bump metallurgical structure 201. However, the buffer metallic layer 220 further includes a first buffer metallic layer 222, a second buffer metallic layer 224 and a third buffer metallic layer 226. The first buffer metallic layer 222, for example, is a lead layer formed over the wettable layer 216. The second buffer metallic layer 224, for example, is a tin layer formed over the first buffer metallic layer 222. The third buffer metallic layer 226, for example, is a lead layer formed between the second buffer metallic layer 224 and the solder bump 18.

FIGS. 2D, 2E and 2F are cross-sectional views of the fourth, fifth and the sixth type of under-bump metallurgical structures between the bonding pad 16 of a die 10 and the solder bump 18. Since the buffer metallic layer 220 of the first type under-bump metallurgical structure 201 as shown in FIG. 2A is capable of wetting the solder bump 18, the wettable layer 216 may be omitted to form the fourth type of under-bump metallurgical structure as shown in FIG. 2D. Similarly, the buffer metallic layer 220 of the second under-bump metallurgical structure 202 as shown in FIG. 2B is capable of wetting the solder bump 18. Hence, the wettable layer 210 may be omitted to form the fifth under-bump metallurgical structure 205 as shown in FIG. 2E. Likewise, the buffer metallic layer 220 of the third under-bump metallurgical structure 203 is capable of wetting the solder bump 18. Consequently, the wettable layer 216 may be omitted to form the sixth type of under-bump metallurgical structure 206 as shown in FIG. 2F.

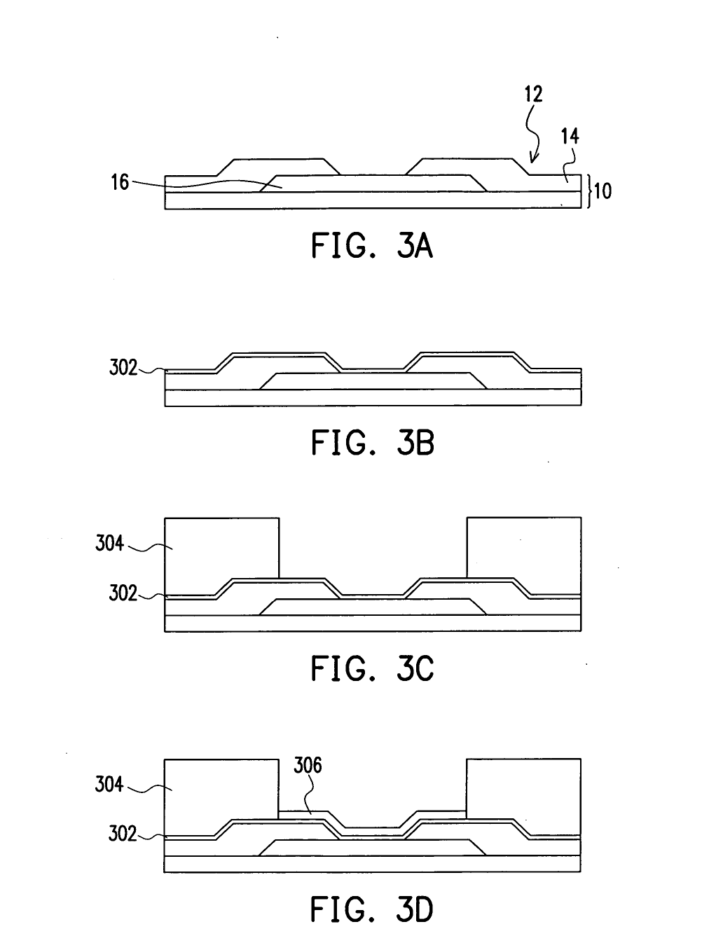

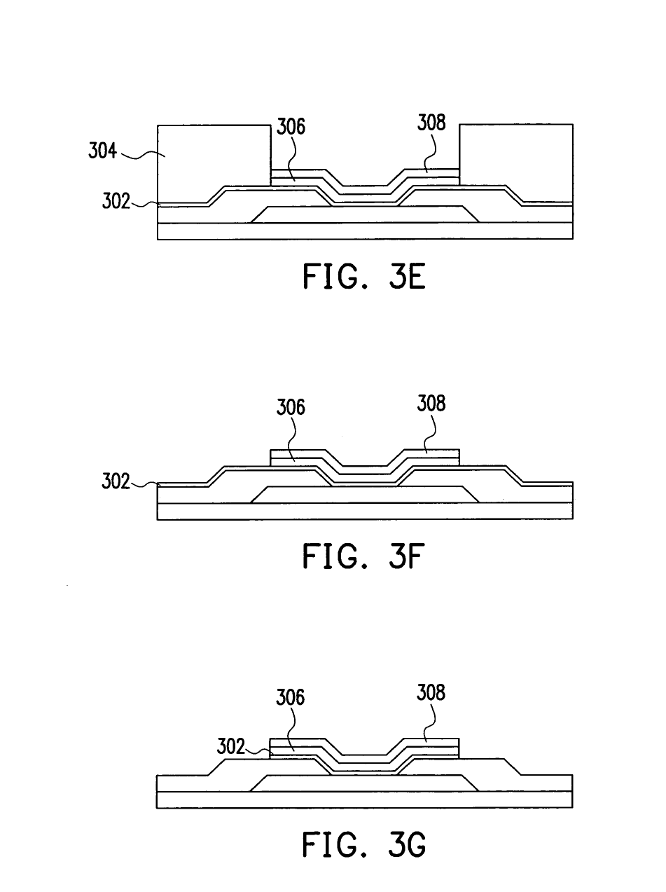

FIGS. 3A to 3G are schematic cross-sectional views showing the progression of steps for fabricating the first type of under-bump metallurgical structure as shown in FIG. 2A. As shown in FIG. 3A, the die 10 has an active surface 12 with a passivation layer 14 and a plurality of bonding pads 16 (only one is shown) thereon. The passivation layer and the bonding pads 16 are formed over the active surface 12 of the die 10 such that the passivation layer 14 exposes the bonding pads 16. As shown in FIG. 3B, a metallic film layer 302 is globally formed over the active surface 12 of the die 10, for example, by evaporation, sputtering or plating. The thin metallic layer 302 serves as a seed layer. As shown in FIG. 3C, a photoresist layer 304 is formed over the thin metallic layer 302 exposing a portion of the thin metallic layer 302 above the bonding pads 16. As shown in FIG. 3D, another metallic layer 306 is formed over the thin metallic layer 302 by plating, evaporation or sputtering, for example. The metallic layer 306 includes an adhesion layer, a barrier layer and a wettable layer. As shown in FIG. 3E, a buffer metallic layer 308 is formed over the metallic layer 306 by plating, for example. As shown in FIG. 3F, the patterned photoresist layer 304 is removed to expose the thin metallic layer 302 underneath but outside the metallic layer 306. Finally, as shown in FIG. 3G, a short etching operation is conducted to remove the thin metallic layer 302 outside the metallic layer 306, thereby forming the first type of under-bump metallurgical structure 201 as shown in FIG. 2A.

Note that the aforementioned paragraph only describes one of the processes that can be used to fabricate the first type of under-bump metallurgical structure 210. Since the steps for producing other types of under-bump metallurgical structures such as 202 to 206 as shown in FIGS. 2B to 2F are very similar, detail descriptions are omitted. In addition, this invention also permits the formation of a mini bump to replace the buffer metallic layer 220 of the under-bump metallurgical structure 201 in FIG. 2A for a further reduction of the growth of inter-metallic compound between the metallic layer and the solder bump.

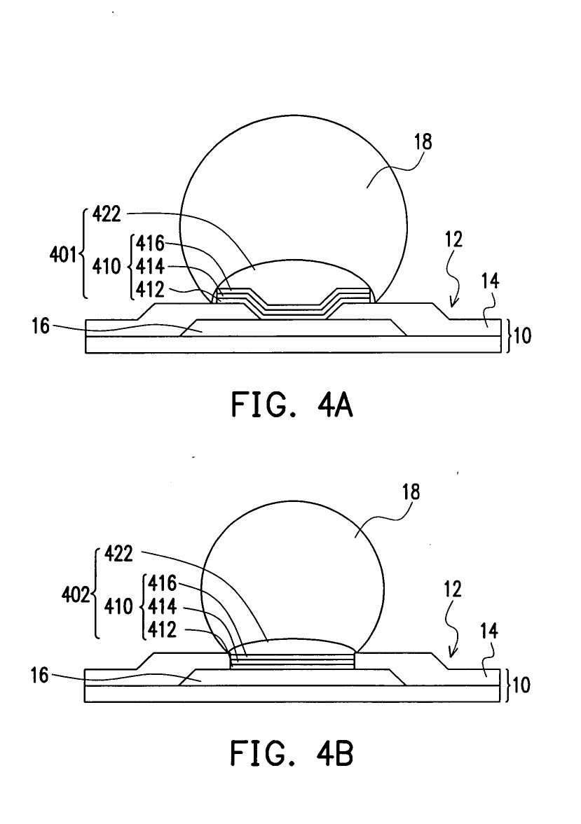

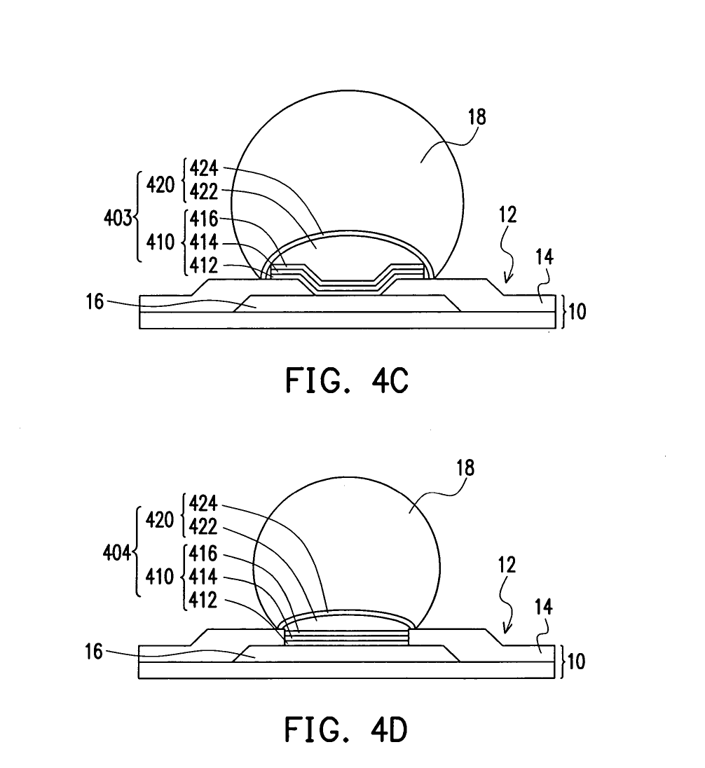

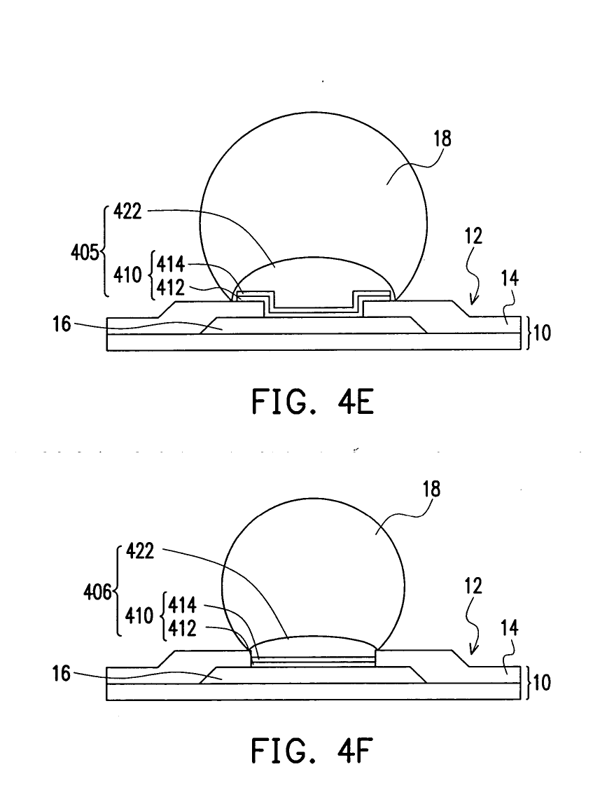

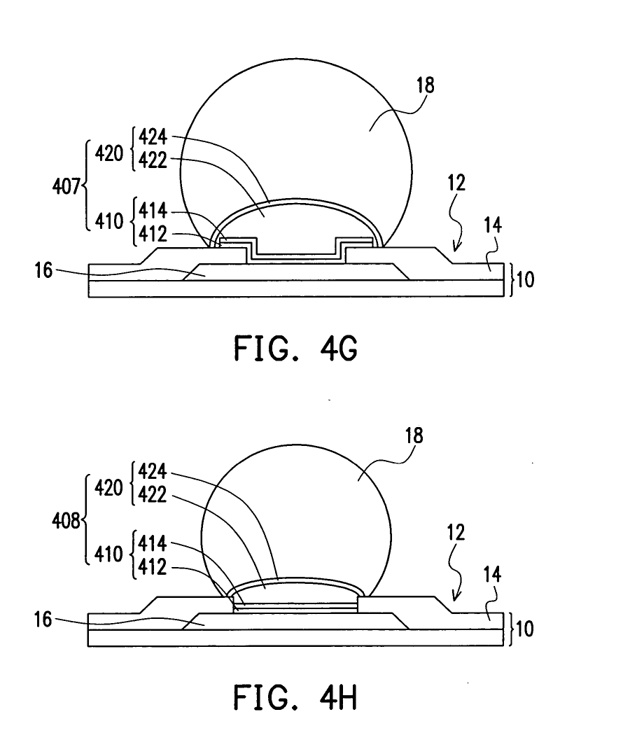

FIG. 4A is a schematic cross-sectional view showing a seventh type of under-bump metallurgical structure between the bonding pad of a die and a solder bump according to a preferred embodiment of this invention. As shown in FIG. 4A, the seventh type of under-bump metallurgical structure 401 includes a metallic layer 410 and a mini bump 422. The metallic layer 410 is formed over a bonding pad 16 and the mini bump 422 is formed between the metallic layer 410 and the solder bump 18. The metallic layer 410 has a material composition identical to the metallic layer in the first type of under-bump metallurgical structure 201. Note that material compositions and properties of the mini bump 422 are identical to the buffer metallic layer 220 in FIG. 2A.

FIG. 4B is a schematic cross-sectional view showing an eighth type of under-bump metallurgical structure between the bonding pad of a die and a solder bump according to a preferred embodiment of this invention. As shown in FIG. 4B, the eighth type of under-bump metallurgical structure 402 has a smaller distribution area compared with the seventh type of under-bump metallurgical structure 401 in FIG. 4A. Hence, the solder bump 18 has a relatively smaller diameter and the pitch between neighboring solder bumps 18 can be reduced.

FIG. 4C is a schematic cross-sectional view showing a ninth type of under-bump metallurgical structure between the bonding pad of a die and a solder bump according to a preferred embodiment of this invention. As shown in FIG. 4C, the buffer metallic structure 420 of the ninth type of under-bump metallurgical structure 403 further includes a mini bump 422 and a buffer metallic layer 424. The mini bump 422 is formed over the metallic layer 410 and the buffer metallic layer 424 is formed between the mini bump 422 and the solder bump 18. The buffer metallic layer 424 is a tin layer, for example.

FIG. 4D is a schematic cross-sectional view showing a tenth type of under-bump metallurgical structure between the bonding pad of a die and a solder bump according to a preferred embodiment of this invention. As shown in FIG. 4D, the tenth type of under-bump metallurgical structure 404 has a smaller distribution area compared with the ninth type of under-bump metallurgical structure 403 in FIG. 4C. Hence, the solder bump 18 has a relatively smaller diameter and the pitch between neighboring solder bumps 18 can be reduced.

FIGS. 4E to 4H are schematic cross-sectional views showing an eleventh, a twelfth, a thirteenth and a fourteenth type of under-bump metallurgical structures between the bonding pad of a die and a solder bump according to a preferred embodiment of this invention. As shown in FIGS. 4E to 4H, the mini bump 422 of the eleventh to the fourteenth types of under-bump metallurgical structures 405 to 408 is capable of wetting the solder bump 18. Hence, the wettable layer 416 in the seventh to the tenth under-bump metallurgical structures as shown in FIGS. 4A to 4D can be omitted to form the eleventh to the fourteenth types of under-bump metallurgical structures. Since the mini bump 422 and the buffer metallic layer 424 has already been explained before, detail description is not repeated here.

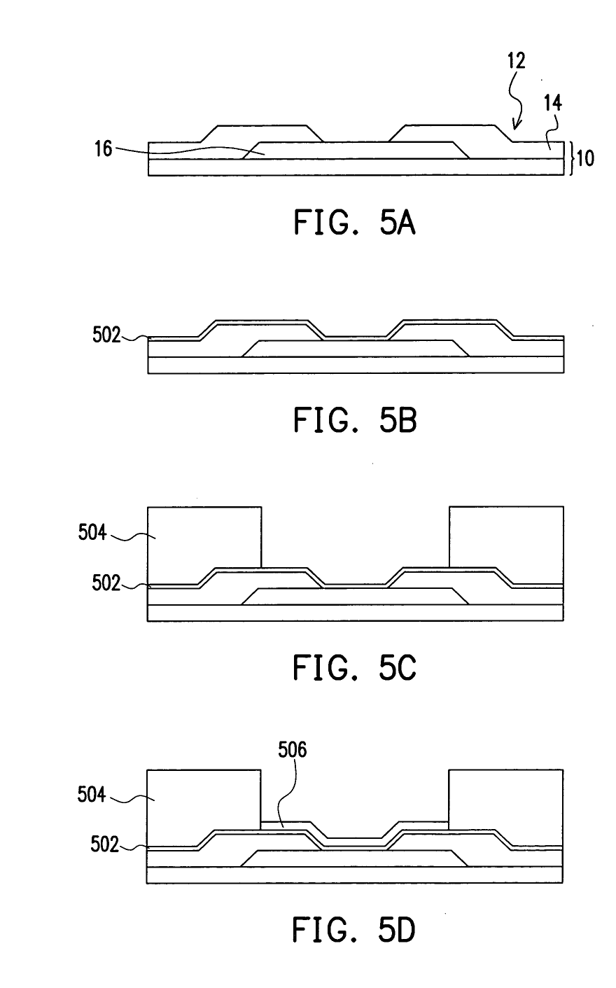

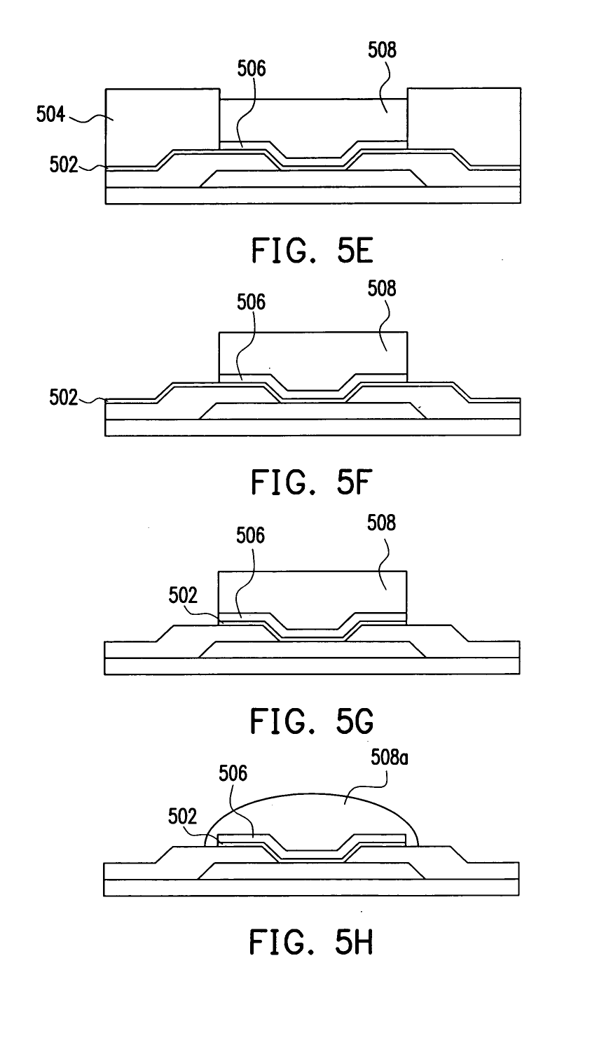

FIGS. 5A to 5H are schematic cross-sectional views showing the progression of steps for fabricating the first type of under-bump metallurgical structure as shown in FIG. 4A. As shown in FIG. 5A, the die 10 has an active surface 12 with a passivation layer 14 and a plurality of bonding pads 16 (only one is shown) thereon. The passivation layer and the bonding pads 16 are formed over the active surface 12 of the die 10 such that the passivation layer 14 exposes the bonding pads 16. As shown in FIG. 5B, a metallic film layer 502 is globally formed over the active surface 12 of the die 10, for example, by evaporation, sputtering or plating. The thin metallic layer 502 serves as a seed layer. As shown in FIG. 5C, a photoresist layer 504 is formed over the thin metallic layer 502 exposing a portion of the thin metallic layer 502 above the bonding pads 16. As shown in FIG. 5D, another metallic layer 506 is formed over the thin metallic layer 502 by plating, evaporation or sputtering, for example. The metallic layer 506 includes an adhesion layer, a barrier layer and a wettable layer. As shown in FIG. 5E, a buffer metallic layer 508 is formed over the metallic layer 506 by plating or printing, for example. As shown in FIG. 5F, the patterned photoresist layer 504 is removed to expose the thin metallic layer 502 underneath but outside the metallic layer 506. As shown in FIG. 5G, a short etching operation is conducted to remove the thin metallic layer 502 outside the metallic layer 506. Finally, as shown in FIG. 5H, a reflow operation may be conducted to transform the buffer metallic layer 508 into a mini bump 508a that encloses the metallic layer 506. However, the aforementioned paragraph only describes one of the processes that can be used to fabricate the seventh type of under-bump metallurgical structure 401. Since the steps for producing other types of under-bump metallurgical structures such as 402 to 408 as shown in FIGS. 4B to 4H are very similar, detail descriptions are omitted.

The under-bump metallurgical structure according to this invention can be applied to a junction interface between the bonding pad of a die and a solder bump. The principle constituent of the solder bump is lead-tin alloy. The under-bump metallurgical structure includes a metallic layer and a buffer metallic structure. The metallic layer is formed over the bonding pads. The principle constituent of the metallic layer is copper, nickel or gold. The buffer metallic structure is formed between the metallic layer and the solder bump for reducing the growth of inter-metallic compound between the metallic layer and the solder bump. The buffer metallic structure may include a buffer metallic layer, a mini bump or a combination of the two. The buffer metallic structure is capable of wetting the solder bump and has a melting point higher than the solder bump. The buffer metallic structure is preferably made from lead.

About the material, the foregoing bump can also be made from a lead-free material, such as SnAg, SnAgBi, SnAgBiCu, SnAgBiCuGe, SnAgBiX, SnAgCu, SnBi, SnCu, SnZn, SnCuSbAg, SnSb or SnZnBi, and the under-bump metallurgical structure can include, for example, Sb, Ag, Sn/Ag, Sn/Cu, and so on. However, if the lead is incuded, it can include, for example, SnPbAg for the bump.

In conclusion, the under-bump metallurgical structure according to this invention is formed between a bonding pad and a solder bump. The under-bump metallurgical structure reduces chemical reaction between tin, a principle constituent within the solder bump, with other metallic materials within the under-bump metallic layer or metallic materials within the bonding pad to form inter-metallic compound. By reducing the growth of inter-metallic compound, electrical resistance between the under-bump metallurgical structure and the solder bump is reduced while bonding strength between the under-bump metallurgical structure and the solder bump is increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An under-bump metallurgical structure between a bonding pad of a die and a solder bump made from a lead-tin alloy or a lead-free alloy, comprising:
a metallic layer over the bonding pad; and
a buffer metallic structure between the metallic layer and the solder bump for reducing the growth of inter-metallic compound between the metallic layer and the solder bump, wherein the buffer metallic structure is properly covered by the solder bump.

2. The under-bump metallurgical structure of claim 1, wherein the principle constituent of the buffer metallic structure is lead.

3. The under-bump metallurgical structure of claim 1, wherein the principle constituent of the buffer metallic structure is lead-tin alloy.

4. The under-bump metallurgical structure of claim 3, wherein the percentage of lead and tin in the lead-tin alloy constituting the buffer metallic structure is about 95% lead and 5% tin.

5. The under-bump metallurgical structure of claim 1, wherein the buffer metallic structure includes a mini bump between the metallic layer and the solder bump, buffer metal is an element of the composition of the solder bump.

6. The under-bump metallurgical structure of claim 5, wherein the principle constituent of the mini bump is lead.

7. The under-bump metallurgical structure of claim 5, wherein the principle constituent of the mini bump is lead-tin alloy.

8. The under-bump metallurgical structure of claim 7, wherein the percentage of lead and tin in the lead-tin alloy constituting the mini bump is about 95% lead and 5% tin.

9. An under-bump metallurgical structure between a bonding pad of a die and a solder bump made from a lead-tin alloy or a lead-free alloy, comprising:
a metallic layer over the bonding pad; and
a buffer metallic structure between the metallic layer and the solder bump for reducing the growth of inter-metallic compound between the metallic layer and the solder bump, wherein the buffer metallic structure is properly covered by the solder bump, and the buffer metallic structure is principally constituent of a element of the composition of the solder bump.

10. The under-bump metallurgical structure of claim 1, wherein the melting point of the buffer metallic structure is higher that that of the solder bump.

11. The under-bump metallurgical structure of claim 1, wherein the thickness of the buffer metallic structure is greater than that of the metallic layer.

12. The under-bump metallurgical structure of claim 1, wherein the thickness of the buffer metallic structure is about 0.5 micron to 10 microns.

13. The under-bump metallurgical structure of claim 1, wherein the alloy formed from the buffer metallic structure with the solder bump is similar to the composition of the solder bump with a continuous phase constitution gradient.

14. The under-bump metallurgical structure of claim 1, wherein the buffer metallic structure includes a mini bump between the metallic layer and the solder bump.

15. The under-bump metallurgical structure of claim 14, wherein the melting point of the mini bump is higher that that of the solder bump.

16. The under-bump metallurgical structure of claim 14, wherein the alloy formed from the mini bump with the solder bump is similar to the composition of the solder bump with a continuous phase constitution gradient.
